(19) United States
(12) Patent Application Publication
(10) Pub. No.: US 2023/0318579 A1
(43) Pub. Date: Oct. 5, 2023

(54) OUTPUT CIRCUIT

(71) Applicant: LAPIS TECHNOLOGY CO., LTD., Kanagawa (JP)

(72) Inventor: SEIICHIRO SASAKI, KANAGAWA (JP)

(21) Appl. No.: 18/126,713

(22) Filed: Mar. 27, 2023

(30) Foreign Application Priority Data
Mar. 29, 2022 (JP) 2022-054207

(51) Int. Cl. H03H 11/28

(52) U.S. Cl. CPC H03H 11/28

(57) ABSTRACT

There is provided an output circuit including: an output terminal at which a high-level signal or a low-level signal is outputted; a first resistance element of which one end is connected to the output terminal, the high-level signal passing through the first resistance element; and a second resistance element of which one end is connected to the output terminal, the low-level signal passing through the second resistance element.

### CROSS-REFERENCE TO RELATED APPLICATION

This application is based on and claims priority under 35 USC 119 from Japanese Patent Application No. 2022-054207 filed on Mar. 29, 2022, the disclosure of which is incorporated by reference herein.

### BACKGROUND

### Technical Field

The present disclosure relates to an output circuit.

### Related Art

A technology described below is known as a technology relating to an output circuit. For example, Japanese Patent Application Laid-Open (JP-A) No. 2009-164718 recites an output buffer circuit that is provided with a delay circuit that delays an input signal by a certain duration, an inversion circuit that inverts the input signal, and an output buffer. The output buffer includes a variable resistance component of an on resistance. A pre-emphasis amount is altered by alteration of a variable resistance value.

The output circuit outputs a high-level signal or a low-level signal from an output terminal. The output circuit includes a CMOS circuit containing a p-channel transistor (a p-MOS) that outputs the high-level signal and an n-channel transistor (an n-MOS) that outputs the low-level signal. A resistance element is provided between output pins of the CMOS circuit (that is, the drain of the p-MOS and the drain of the n-MOS) and the output terminal. The resistance element is for adjusting an output impedance to a desired magnitude. According to the output circuit with the structure described above, the high-level signal and the low-level signal are outputted from the output terminal via the common resistance element.

When, for example, a circuit is added to a power supply line, a power supply side impedance becomes greater than a ground side impedance. In this situation, because the resistance element is employed for both the high-level signal and the low-level signal, adjusting the output impedance may be difficult. For example, in the USB 2.0 specification, an output impedance is stipulated to be 36 Ω±8Ω. A tolerance margin with respect to this specification may be almost entirely taken up.

### SUMMARY

The present invention has been devised in consideration of the matter described above; an object of the present disclosure is to suppress a difference between an output impedance when a high-level signal is outputted and an output impedance when a low-level signal is outputted.

An output circuit according to the present disclosure includes: an output terminal at which a high-level signal or a low-level signal is outputted; a first resistance element of which one end is connected to the output terminal, the high-level signal passing through the first resistance element; and a second resistance element of which one end is connected to the output terminal, the low-level signal passing through the second resistance element.

According to the present disclosure, a difference between the output impedance when the high-level signal is outputted and the output impedance when the low-level signal is outputted may be suppressed.

### BRIEF DESCRIPTION OF THE DRAWINGS

Exemplary embodiments of the present disclosure will be described in detail based on the following figures, wherein:

FIG. 1 is a diagram showing an example of structures of an output circuit according to a first exemplary embodiment of the present disclosure;

FIG. 2 is a diagram showing an example of structures of an output circuit according to a comparative example;

FIG. 3 is a diagram showing an example of structures of an output circuit according to a second exemplary embodiment of the present disclosure; and

FIG. 4 is a diagram showing an example of structures of an output circuit according to a third exemplary embodiment of the present disclosure.

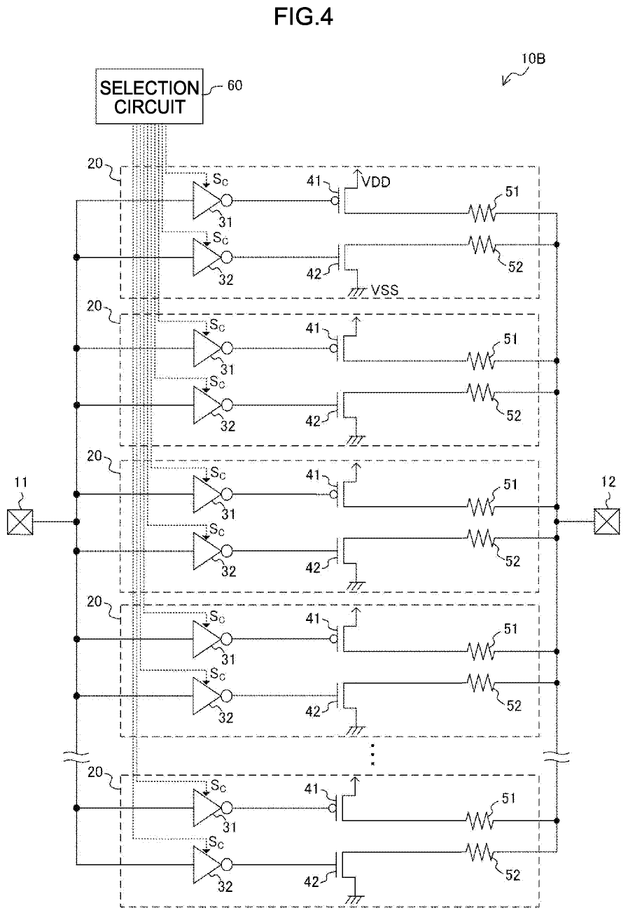

### DETAILED DESCRIPTION

Below, exemplary embodiments of the present disclosure are described with reference to the drawings. In the drawings, the same reference symbols are assigned to structural elements or portions that are substantially the same or equivalent.

### First Exemplary Embodiment

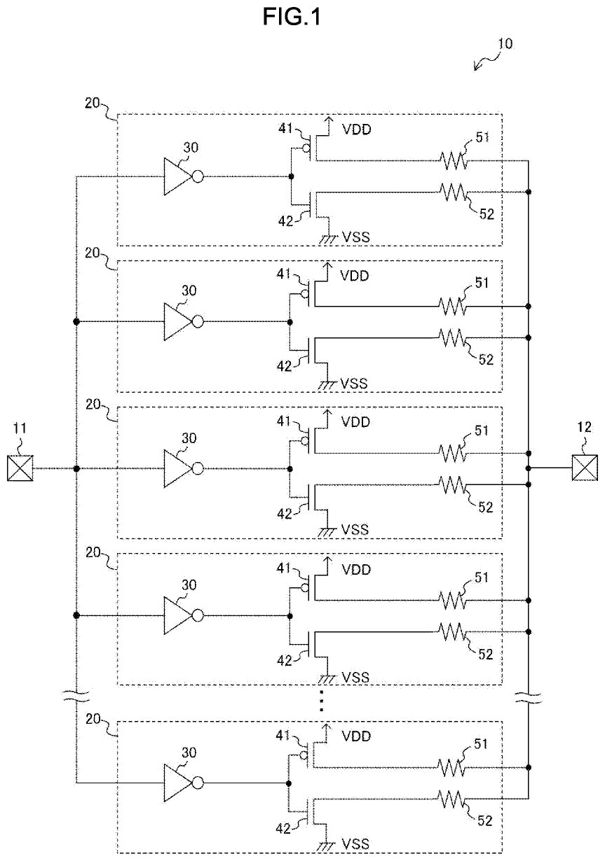

FIG. 1 is a diagram showing an example of structures of an output circuit 10 according to a first exemplary embodiment of the present disclosure. The output circuit 10 includes an input terminal 11 at which an input signal is inputted, an output terminal 12 at which a high-level signal or a low-level signal is outputted depending on the input signal, and plural circuit blocks 20 that are provided in parallel between the input terminal 11 and the output terminal 12. The plural circuit blocks 20 have the same structure as one another. Each of the plural circuit blocks 20 includes a pre-driver 30, a p-channel transistor 41 (below denoted as a p-MOS), an n-channel transistor 42 (below denoted as an n-MOS), a resistance element 51 and a resistance element 52.

An input pin of the pre-driver 30 is connected to the input terminal 11, and an output pin of the pre-driver 30 is connected to the gates of the p-MOS 41 and the n-MOS 42. The pre-driver 30 drives the p-MOS 41 and the n-MOS 42. The pre-driver 30 may have, for example, a CMOS inverter structure, outputting signals that invert the logic level of input signals inputted to the input terminal 11.

The gates of the p-MOS 41 and n-MOS 42 are connected to one another, structuring a CMOS circuit. The source of the p-MOS 41 is connected to a power supply line VDD. The drain of the p-MOS 41 is connected to one end of the resistance element 51. The source of the n-MOS 42 is connected to a ground line VSS. The drain of the n-MOS 42 is connected to one end of the resistance element 52.

When an output signal from the pre-driver 30 is at the low level, the p-MOS 41 turns on and outputs a high-level signal, and when an output signal from the pre-driver 30 is at the high level, the p-MOS 41 turns off. When an output signal from the pre-driver 30 is at the high level, the n-MOS 42 turns on and outputs a low-level signal, and when an output signal from the pre-driver 30 is at the low level, the n-MOS 42 turns off. The p-MOS 41 is an example of a first transistor of the present disclosure and the n-MOS 42 is an example of a second transistor of the present disclosure.

One end of the resistance element 51 is connected to the output terminal 12 and the other end of the resistance element 51 is connected to the drain of the p-MOS 41. The high-level signal outputted from the p-MOS 41 passes through the resistance element 51 and is outputted through the output terminal 12. The resistance elements 51 may be same as one another between the circuit blocks 20, and may be different from one another. One end of the resistance element 52 is connected to the output terminal 12 and the other end of the resistance element 52 is connected to the drain of the n-MOS 42. The low-level signal outputted from the p-MOS 41 passes through the resistance element 51 and is outputted through the output terminal 12. The resistance elements 52 may be same as one another between the circuit blocks 20, and may be different from one another. The resistance element 51 is an example of a first resistance element of the present disclosure and the resistance element 52 is an example of a second resistance element of the present disclosure.

When a high-level input signal is inputted to the input terminal 11, the p-MOS 41 in each of the plural circuit blocks 20 turns on. A high-level signal is outputted from each p-MOS 41 and is outputted through the output terminal 12 via the corresponding resistance element 51.

An impedance (Z_{P}+Z_{RH}) is the sum of an impedance Z_{P} corresponding to the on resistance of the p-MOS 41 and an impedance Z_{RH} due to the resistance element 51. When the impedances (Z_{P}+Z_{RH}) are the same as one another between the circuit blocks 20, an output impedance Z_{OUTH} when the high-level signal is outputted from the output circuit 10 can be expressed by the following expression (1). The symbol n in expression (1) is the number of the circuit blocks 20 that are in parallel.

Z_{OUTH}=(Z_{P}+Z_{RH})/n (1)

Similarly, an impedance (Z_{N}+Z_{RL}) is the sum of an impedance Z_{N} corresponding to the on resistance of the n-MOS 42 and an impedance Z_{RL} due to the resistance element 52. When the impedances (Z_{N}+Z_{RL}) are the same as one another between the circuit blocks 20, an output impedance Z_{OUTL} when the low-level signal is outputted from the output circuit 10 can be expressed by the following expression (2). The symbol n in expression (2) is the number of the circuit blocks 20 in parallel.

Z_{OUTL}=(Z_{N}+Z_{RL})/n (2)

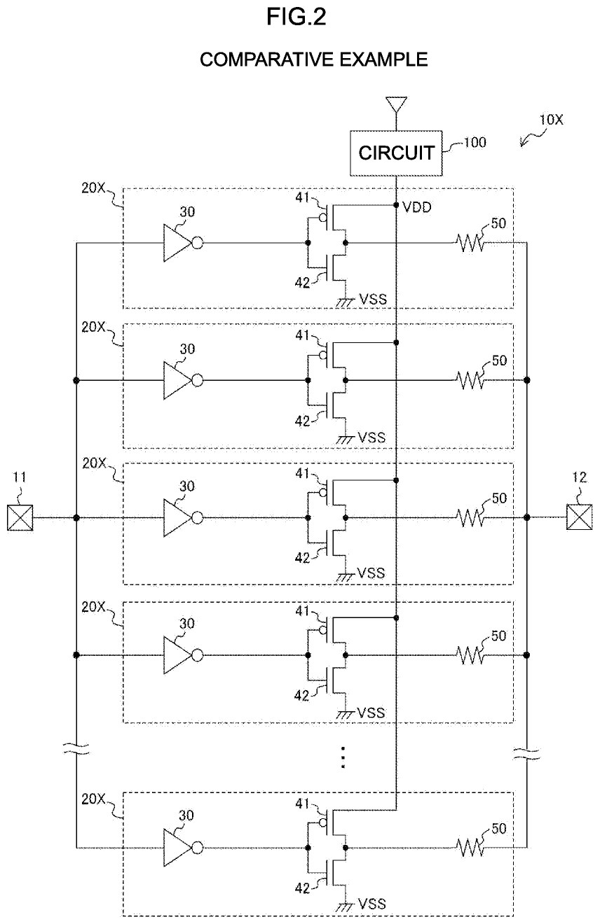

FIG. 2 is a diagram showing an example of structures of an output circuit 10X relating to a comparative example. In each of circuit blocks 20X that structure the output circuit 10X relating to the comparative example, the drain of the p-MOS 41 and the drain of the n-MOS 42 are connected to one another, one end of a resistance element 50 is connected to the output terminal 12, and the other end of the resistance element 50 is connected to a junction with the drain of the p-MOS 41 and the drain of the n-MOS 42. In the output circuit 10X according to the comparative example, the high-level signal outputted from the p-MOS 41 and the low-level signal outputted from the n-MOS 42 both pass through the same resistance element 50 and are outputted through the output terminal 12. The output circuit 10X according to the comparative example includes a circuit 100 that is added to the power supply line VDD. The circuit 100 may be, for example, a switching circuit that switches a power supply voltage supplied to the power supply line VDD.

An impedance (Z_{P}+Z_{RX}) is the sum of the impedance Z_{P} corresponding to the on resistance of the p-MOS 41 and an impedance Z_{RX} due to the resistance element 50. When the impedances (Z_{P}+Z_{RX}) are the same as one another between the circuit blocks 20X, an output impedance Z_{OUTH} when the high-level signal is outputted from the output circuit 10X according to the comparative example can be expressed by the following expression (3). The symbol n in expression (3) is the number of the circuit blocks 20X in parallel, and the symbol Z_{C} is an impedance due to the circuit 100.

Z_{OUTH}=Z_{C}+(Z_{P}+Z_{RX})/n (3)

Similarly, an impedance (Z_{N}+Z_{RX}) is the sum of the impedance Z_{N} corresponding to the on resistance of the n-MOS 42 and the impedance Z_{RX} due to the resistance element 50. When the impedances (Z_{N}+Z_{RX}) are the same as one another between the circuit blocks 20X, an output impedance Z_{OUTL} when the low-level signal is outputted from the output circuit 10X according to the comparative example can be expressed by the following expression (4). The symbol n in expression (4) is the number of the circuit blocks 20X in parallel.

Z_{OUTL}=(Z_{N}+Z_{RX})/n (4)

According to the output circuit 10X according to the comparative example, because the circuit 100 is added, the impedance at the power supply side is greater than the impedance at the ground side. Therefore, with the resistance elements 50 that are used for both high-level signals and low-level signals, adjusting the output impedance may be difficult. For example, in the USB 2.0 specification, an output impedance is stipulated to be 36 Ω±8Ω. A tolerance margin with respect to this specification may be almost entirely taken up.

In contrast, according to the output circuit 10 according to the present exemplary embodiment, the resistance element 51 through which the high-level signal passes and the resistance element 52 through which the low-level signal passes are structured by separate resistance elements. Therefore, Z_{RH} in expression (1) and Z_{RL} in expression (2) may be adjusted independently. Thus, the output impedance Z_{OUTH} when the high-level signal is outputted and the output impedance Z_{OUTL} when the low-level signal is outputted may be adjusted independently. When, for example, a circuit is added to the power supply line VDD as illustrated in FIG. 2 and the impedance at the power supply side is greater than the impedance at the ground side, a difference between the output impedance when the high-level signal is outputted and the output impedance when the low-level signal is outputted may be reduced by setting the resistance value of the resistance element 51 smaller than the resistance value of the resistance element 52. As a result, a tolerance margin with respect to an output impedance specification may be assured.

### Second Exemplary Embodiment

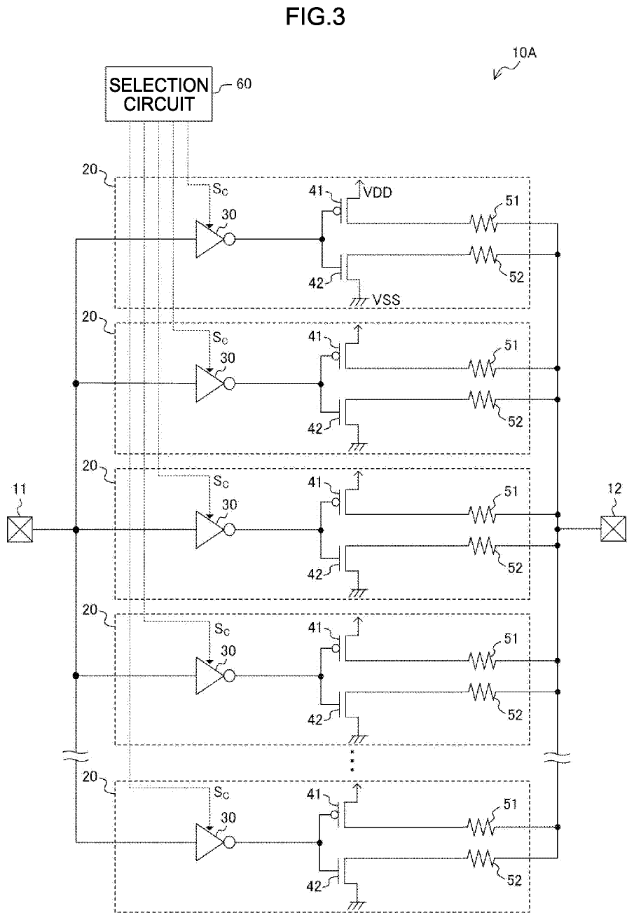

FIG. 3 is a diagram showing an example of structures of an output circuit 10A according to a second exemplary embodiment of the present disclosure. The output circuit 10A includes a selection circuit 60. The selection circuit 60 selectively activates the pre-drivers 30 that are respectively included in the plural circuit blocks 20. By supplying control signals SC to the pre-drivers 30, the selection circuit 60 designates which of the pre-drivers 30 are activated.

Of the plural circuit blocks 20, only each circuit block 20 including an activated pre-driver 30 effectively functions. Thus, the number of the circuit blocks 20 that are in parallel can be specified through selection of the pre-drivers 30. That is, through selection of the pre-drivers 30, the number of resistance elements 51 and resistance elements 52 that are in parallel can be specified, implementing adjustment of the output impedances.

For example, if the voltage applied to the power supply line VDD is altered when the high-level signal is outputted, the output impedance Z_{OUTH} when the high-level signal is outputted may be calculated by monitoring an output voltage and output current at the output terminal 12. Similarly, if the voltage applied to the power supply line VDD is altered when the low-level signal is outputted, the output impedance Z_{OUTL} when the low-level signal is outputted may be calculated by monitoring the output voltage and output current at the output terminal 12.

According to the output circuit 10A according to the present exemplary embodiment, the output impedance Z_{OUTH} when the high-level signal is outputted and the output impedance Z_{OUTL} when the low-level signal is outputted, which are calculated as described above, may be matched to a target value by setting respective numbers of the pre-drivers 30 (that is, numbers of the resistance elements 51 and resistance elements 52 that are in parallel) to be activated such that the output impedances Z_{OUTH} and Z_{OUTL} are as close as possible to the target value. As a result, a tolerance margin with respect to an output impedance specification may be further increased. When the resistance values of the respective resistance elements 51 and 52 are different from one another between the circuit blocks 20, the tolerance margin with respect to the output impedance specification may be increased even further by setting combinations of the pre-drivers 30 to be activated.

### Third Exemplary Embodiment

FIG. 1 is a diagram showing an example of structures of an output circuit 10B according to a third exemplary embodiment of the present disclosure. In the output circuit 10A according to the second exemplary embodiment that is described above, the pair of the p-MOS 41 and n-MOS 42 that structure each CMOS circuit are driven in common by the pre-driver 30. In contrast, in the output circuit 10B according to the third exemplary embodiment, the pair of the p-MOS 41 and n-MOS 42 structuring each CMOS circuit are driven by separate pre-drivers. That is, each circuit block 20 of the output circuit 10B includes a first pre-driver 31 that drives the p-MOS 41 and a second pre-driver 32 that drives the n-MOS 42.

The output circuit 10B includes the selection circuit 60. The selection circuit 60 selectively activates the first pre-drivers 31 respectively included in the plural circuit blocks 20 and selectively activates the plural second pre-drivers 32. Selections of the first pre-drivers 31 and selections of the second pre-drivers 32 may be conducted independently. That is, a selection may be conducted in which the first pre-driver 31 of a circuit block 20 is activated but the second pre-driver 32 of that circuit block 20 is not activated.

According to the output circuit 10B according to the present exemplary embodiment, the number of the resistance elements 51 that are in parallel may be specified through selection of the first pre-drivers 31, and the number of the resistance elements 52 that are in parallel may be specified through selection of the second pre-drivers 32. That is, numbers of the resistance element 51 in parallel and numbers of the resistance elements 52 in parallel may be specified independently. Thus, the output impedances Z_{OUTH} and Z_{OUTL} may be matched to a target value independently from one another, and a tolerance margin with respect to an output impedance specification may be further increased.

When the resistance values of the respective resistance elements 51 and 52 are different from one another between the circuit blocks 20, the tolerance margin with respect to the output impedance specification may be increased even further by respectively setting combinations of the first pre-drivers 31 to be activated and combinations of the second pre-drivers 32 to be activated.

What is claimed is:

1. An output circuit comprising:
an output terminal at which a high-level signal or a low-level signal is outputted;
a first resistance element of which one end is connected to the output terminal, the high-level signal passing through the first resistance element; and
a second resistance element of which one end is connected to the output terminal, the low-level signal passing through the second resistance element.

2. The output circuit according to claim 1, further comprising:
a first transistor connected to another end of the first resistance element, the first transistor outputting the high-level signal;
a second transistor connected to another end of the second resistance element, the second transistor outputting the low-level signal; and
a pre-driver that drives the first transistor and the second transistor.

3. The output circuit according to claim 2, comprising a plurality of circuit blocks, each circuit block including the first resistance element, the second resistance element, the first transistor, the second transistor and the pre-driver.

4. The output circuit according to claim 3, further comprising a selection circuit that outputs control signals for selectively activating the pre-drivers respectively included in the plurality of circuit blocks.

5. The output circuit according to claim 3, wherein resistance values of the first resistance elements respectively included in the plurality of circuit blocks are different from one another.

6. The output circuit according to claim 3, wherein resistance values of the second resistance elements respectively included in the plurality of circuit blocks are different from one another.

7. The output circuit according to claim 2, wherein the pre-driver includes:
a first pre-driver that drives the first transistor, and
a second pre-driver that drives the second transistor.
